(19) United States
(12) Patent Application Publication
(10) Pub. No.: US 2025/0218820 A1
(43) Pub. Date: Jul. 3, 2025

(54) STAMP FOR TRANSFERRING LIGHT-EMITTING ELEMENTS AND METHOD FOR FABRICATING DISPLAY DEVICE USING THE SAME

(71) Applicant: LG Display Co., Ltd., Seoul (KR)

(72) Inventors: Chan KIM, Paju-si (KR); Bong Seok CHOI, Paju-si (KR); Seok Hwan JUNG, Paju-si (KR)

(73) Assignee: LG Display Co., Ltd., Seoul (KR)

(21) Appl. No.: 19/002,258

(22) Filed: Dec. 26, 2024

(30) Foreign Application Priority Data
Dec. 27, 2023 (KR) 10-2023-0193126

(51) Int. Cl. H01L 21/67; H10H 29/01; H10H 29/02

(52) U.S. Cl. CPC H01L 21/67144; H10H 29/012; H10H 29/02

(57) ABSTRACT

A light-emitting element transfer stamp can include a stamp substrate, an elastic part disposed on the stamp substrate, a pickup portion disposed on the elastic portion, and a damper part connected to the elastic part. A method for fabricating a display device using the light-emitting element transfer stamp is also discussed.

### CROSS-REFERENCE TO RELATED APPLICATION

This application claims priority to Korean Patent Application No. 10-2023-0193126, filed in the Republic of Korea on Dec. 27, 2023, the entirety of which is hereby expressly incorporated by reference into the present application.

### BACKGROUND

### Technical Field

The present disclosure relates to a display device, and more particularly to a stamp for transferring light-emitting elements and a method for fabricating a display device using the same.

### Discussion of the Related Art

Electroluminescent display devices include an organic light emitting display device in which an organic light emitting diode (OLED) is disposed, and an inorganic light emitting display device (hereinafter referred to as an “LED display device”) in which an inorganic light emitting diode (hereinafter referred to as an “LED”) is disposed.

Since the electroluminescent display device displays an image using a spontaneous emission element, it does not require a separate light source, e.g., a backlight unit, so that it can be implemented in thin and various forms.

Recently, as an example of the inorganic light emitting display device, a micro-LED display device in which micro-LEDs are disposed in pixels has been gaining attention as a next generation display device.

The micro-light-emitting element (μ-LED) refers to an ultra-small inorganic light-emitting element having a size of 100 μm or less. Using such a micro-light-emitting element as a pixel makes it possible to miniaturize and lighten the device.

In order to fabricate a display device using the micro-light-emitting elements, the micro-light-emitting element can be crystallized on a substrate such as sapphire or silicon, and the crystallized micro-light-emitting element can be transferred to a substrate having a driving circuit. In order to transfer the micro-light-emitting element, a method of transferring a plurality of micro-light-emitting elements onto the substrate on which the driving circuit is formed, using a stamp that picks up the plurality of micro-light-emitting elements, can be used.

### SUMMARY OF THE DISCLOSURE

An object of the present disclosure is to provide a stamp for transferring light-emitting elements and a method for fabricating a display device using the same, which can improve the transfer yield of light-emitting element chips by reducing or preventing the vibration generated in a spring during a light-emitting element chip transfer process using the stamp applied with a spring damper.

Another object of the present disclosure is to address other limitations and disadvantages associated with the related art.

The problems to be solved by the features of the present disclosure are not limited to the problem mentioned above, and other problems not mentioned herein will be clearly understood by those skilled in the art from the following description.

A stamp for transferring light-emitting elements according to one embodiment of the present disclosure includes at least one pickup portion configured to pick up a light-emitting element; a substrate configured to move the at least one pickup portion; an elastic part disposed between the pickup portion and the substrate; and a damper part configured to absorb vibration generated in the elastic part.

A method for fabricating a display device according to one embodiment of the present disclosure includes preparing a stamp including at least one pickup portion configured to pick up a light-emitting element, a first substrate configured to move the at least one pickup portion, an elastic part disposed between the pickup portion and the first substrate, and a damper part configured to absorb vibration generated in the elastic part; preparing a growth substrate on which a plurality of light-emitting elements are formed; preparing a display panel in which display areas including a pixel area having a plurality of emission regions are disposed, and a panel substrate on which a pixel driving circuit configured to drive pixels of the display panel is disposed; picking up the plurality of light-emitting elements of the growth substrate using the at least one pickup portion of the stamp; transferring the plurality of light-emitting elements picked up by the stamp to the plurality of emission regions of the display panel disposed on the panel substrate.

According to aspects of the present disclosure, it is possible to improve the transfer yield of light-emitting element chips by reducing or minimizing the vibration generated in a spring during the light-emitting element chip transfer process using the stamp equipped with a spring damper.

According to aspects of the present disclosure, a spring damper is disposed in the stamp to induce uniform contact and load between the stamp and the light-emitting element chip while damping the spring vibration of the stamp, thereby minimizing or preventing an issue of light-emitting element chips which can be picked up by the stamp being dropped or misaligned when transferred to the substrate.

The effects of the present disclosure are not limited to the above-mentioned effects, and other effects that are not mentioned will be apparently understood by those skilled in the art from the following description and the appended claims.

### BRIEF DESCRIPTION OF THE DRAWINGS

The above and other objects, features, and advantages of the present disclosure will become more apparent to those of ordinary skill in the art by describing exemplary embodiments thereof in detail with reference to the attached drawings, in which:

FIG. 1 is a diagram illustrating a display device according to aspects of the present disclosure;

FIG. 2 is an enlarged view of area A of FIG. 1;

FIG. 3 is a diagram illustrating a partial area of a pixel according to aspects of the present disclosure;

FIG. 4 is a cross-sectional view taken along line I-I′ in FIG. 3;

FIG. 5 is a cross-sectional view taken along line II-II′ in FIG. 3;

FIG. 6 is an enlarged view of an area B of FIG. 5;

FIGS. 7A and 7B are perspective views illustrating a process of picking up and transferring a light-emitting element using a stamp according to one embodiment of the present disclosure;

FIG. 8 is a plan view illustrating a stamp according to one embodiment of the present disclosure;

FIG. 9 is an enlarged perspective view of an area C of FIG. 8;

FIG. 10 is a cross-sectional view taken along line III-III′ in FIG. 9.

FIGS. 11A to 11F are cross-sectional views illustrating a process of picking up and transferring a light-emitting element using a stamp according to one embodiment of the present disclosure;

FIG. 12 is a diagram illustrating an example of the change in amplitude over time during the pickup of a light-emitting element using a stamp having an elastic part and a damper part according to one embodiment of the present disclosure, and a stamp having only a spring;

FIGS. 13A to 13L are cross-sectional views of a stamp fabricating process according to one embodiment of the present disclosure;

FIG. 14 is a diagram illustrating a stamp according to a second embodiment of the present disclosure;

FIG. 15 is a diagram illustrating a stamp according to a third embodiment of the present disclosure;

FIG. 16 is a diagram illustrating a stamp according to a fourth embodiment of the present disclosure;

FIG. 17 is a diagram illustrating a stamp according to a fifth embodiment of the present disclosure; and

FIGS. 18A to 18D are cross-sectional views of a stamp fabricating process according to the fourth embodiment of FIG. 16.

### DETAILED DESCRIPTION OF THE EMBODIMENTS

The advantages and features of the present disclosure, and methods of achieving them will become apparent upon reference to the embodiments described in detail below in conjunction with the accompanying drawings. However, the present disclosure is not limited to the following embodiments, but can be implemented in various different forms; rather, the present embodiments are provided to make the disclosure of the present specification complete and to enable those skilled in the art to fully understand the scope of the present disclosure.

The shapes, sizes, proportions, angles, numbers, and the like of elements shown in the drawings to illustrate embodiments of the present disclosure are merely illustrative and are not intended to be limiting. Further, in describing the present disclosure, detailed descriptions of well-known technologies can be omitted so as not to obscure the essence of the present disclosure.

The terms such as “comprising,” “having,” and “consisting of” used herein are generally intended to allow for the addition of other components unless the terms are used with the term “only.” References to components of a singular noun include the plural of that noun, unless specifically stated otherwise.

In interpreting components, they are construed to include a margin of error, even if it is not explicitly stated.

When describing the positional relationship, for example, if the positional relationship of the two parts is described as “on,” “above,” “below,” and “next to,” one or more other parts can be located between the two parts unless “immediately” or “directly” is used.

When an element or layer is referred to as being on another element or layer, this includes any intervening layer or other element directly on top of or in between the other element.

In addition, first, second, etc., are used to describe various components, but these components are not limited by these terms. These terms are used only to distinguish one component from another. Therefore, the first component referred to below can be a second component within the technical spirit of the present disclosure.

Identical reference numerals can designate identical components throughout the description.

The sizes and thicknesses of each configuration shown in the drawings are shown for illustrative purposes only and are not necessarily limited to the sizes and thicknesses of the configurations shown herein.

Each of the features of various embodiments described herein can be coupled or combined with one another in whole or in part, and can be technologically interlocked and operated in various ways, and each of the embodiments can be carried out independently or in conjunction with one another. Further, the term “can” fully encompasses all the meanings and coverages of the term “may.”

Hereinafter, various embodiments of the present disclosure will be described in detail with reference to the accompanying drawings. All the components of each display device according to all embodiments of the present disclosure are operatively coupled and configured.

A display device according to one or more embodiments of the present disclosure includes a display panel having a display area or screen on which an image is displayed, and a pixel driving circuit that drives pixels of the display panel. The display area includes a pixel area in which the pixels are arranged. The pixel area includes a plurality of light-emitting areas. A light-emitting element is disposed in each of the light-emitting areas. The pixel driving circuit can be embedded in the display panel.

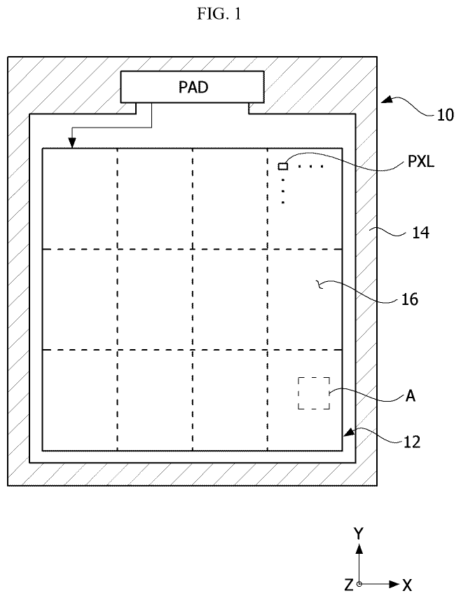

FIG. 1 is a diagram illustrating a display device according to one embodiment of the present disclosure.

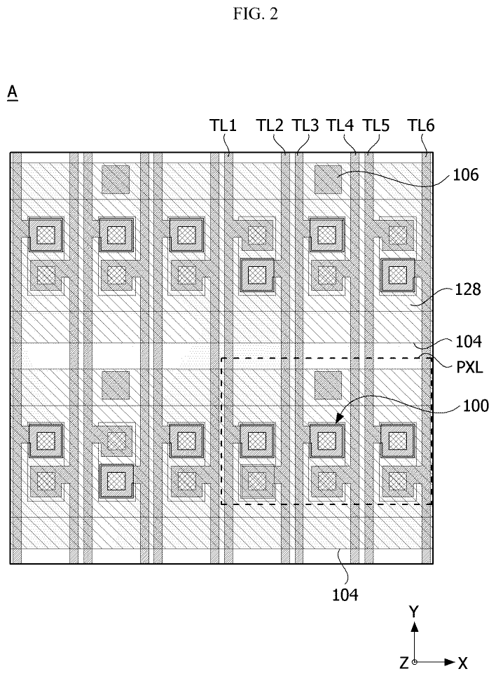

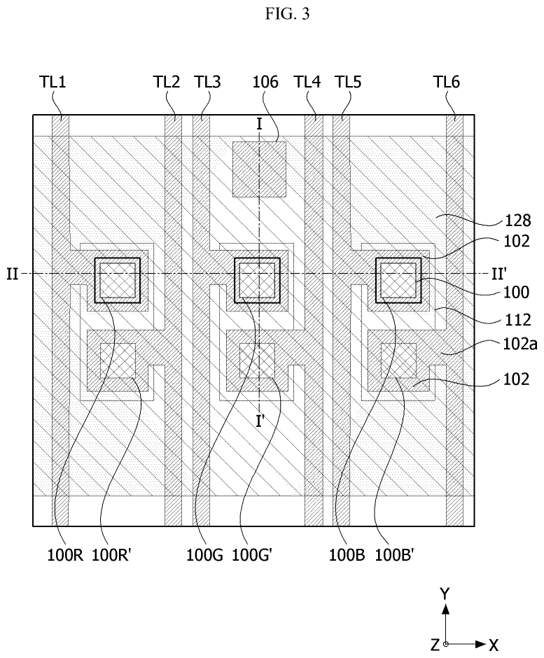

FIG. 2 is an enlarged view of an area A in FIG. 1. FIG. 3 is a diagram illustrating a partial area of a pixel according to aspects of the present disclosure.

Referring to FIGS. 1 and 2, a display device 10 according to an embodiment of the present disclosure includes a display panel on which an input image is visually reproduced. The display panel can include a display area 12 in which the image is displayed and a non-display area 14 in which no image is displayed. In the non-display area 14, various wires and driving circuits can be mounted and a pad portion PAD can be disposed to which integrated circuits, printed circuits, etc. are connected.

A plurality of light-emitting elements 100 disposed in the display area 12 to form the pixels PXL can be micro-sized inorganic light-emitting elements. The inorganic light-emitting elements can be grown on a silicon wafer and then attached to the display panel through a transfer process.

Referring to FIGS. 1 to 3, the transfer process of the light-emitting element 100 can be performed for each pre-divided region. Although FIG. 1 illustrates that the display area 12 is divided into twelve transfer regions 16, the size of the transfer region or the number of divisions of the transfer regions is not limited thereto. The transfer process can be sequentially or simultaneously performed in a first transfer region 16 to a twelfth transfer region 16. Red light-emitting elements 100R and 100R′, green light-emitting elements 100G and 100G′, and blue light-emitting elements 100B and 100B′ can be sequentially transferred to the transfer regions 16.

In the non-display area 14, a data driving circuit or a gate driving circuit can be disposed and wires for supplying a control signal for controlling the driving circuits can be disposed. Here, the control signal can include various timing signals including a clock signal, an input data enable signal, and synchronization signals, and can be received through the pad portion PAD.

The pixels PXL can be driven by the pixel driving circuit. The pixel driving circuit can receive a driving voltage, an image signal (digital signal), a synchronization signal synchronized with the image signal, and the like and output an anode voltage and a cathode voltage of the light-emitting element 100 to drive the plurality of pixels. The driving voltage can be a high potential voltage EVDD. The cathode voltage can be a low potential voltage EVSS commonly applied to the pixels. The anode voltage can be a voltage corresponding to a pixel data value of the image signal. The pixel driving circuit can be disposed in the non-display area 14 or can be disposed below the display area 12.

Each of the pixels PXL can include a plurality of sub-pixels having different colors. For example, the plurality of pixels can include a red sub-pixel in which the light-emitting element 100 that emits light of a red wavelength is disposed, a green sub-pixel in which the light-emitting element 100 that emits light of a green wavelength is disposed, and a blue sub-pixel in which the light-emitting element 100 that emits light of a blue wavelength is disposed. The plurality of pixels can further include a white sub-pixel.

Referring to FIGS. 2 and 3, the plurality of pixels PXL can be successively arranged in the first direction (e.g., the X-axis direction) and the second direction (the Y-axis direction). A plurality of sub-pixels of the same color can be disposed within the pixel of the display area 12. For example, each of the plurality of pixels can include a first red sub-pixel in which a first-first red light-emitting element 100R that emits light of a red wavelength is disposed, a second red sub-pixel in which a first-second red light-emitting element 100R′ that emits light of a red wavelength is disposed, a first green sub-pixel in which a second-first green light-emitting element 100G that emits light of a green wavelength is disposed, a second green sub-pixel in which a second-second green light-emitting element 100G′ that emits light of a green wavelength is disposed, a first blue sub-pixel in which a third-first blue light-emitting element 100B that emits light of a blue wavelength is disposed, and a second blue sub-pixel in which a third-second light-emitting element 100B′ that emits light of a blue wavelength is disposed. The first-first red light-emitting element 100R, the second-first green light-emitting element 100G, and the third-first blue light-emitting element 100B can be regarded as main light-emitting elements. The first-second red light-emitting element 100R′, the second-second green light-emitting element 100G′, and the third-second blue light-emitting element 100B′ can be regarded as sub-light-emitting elements.

One sub-pixel can include at least one or more light-emitting elements, and if one light-emitting element becomes defective, the luminance of another light-emitting element can be increased to adjust the luminance of the sub-pixel. However, the embodiment is not necessarily limited thereto, and one sub-pixel can include only one light-emitting element.

A plurality of first electrodes 102 can be disposed on the lower portion of the light-emitting element 100, respectively, and can be selectively connected to a plurality of signal wires TL1 to TL6 by an extension portion 102a. The high potential voltage can be applied to the pixel driving circuit through the signal wires TL1 to TL6. The signal wires TL1 to TL6 and the first electrode 102 can be formed as integrated electrode patterns during the electrode patterning process.

For example, a first signal wire TL1 can be connected to an anode electrode of the first red sub-pixel, and a second signal wire TL2 can be connected to an anode electrode of the second red sub-pixel. A third signal wire TL3 can be connected to an anode electrode of the first green sub-pixel, and a fourth signal wire TL4 can be connected to an anode electrode of the second green sub-pixel. A fifth signal wire TL5 can be connected to an anode electrode of the first blue sub-pixel, and a sixth signal wire TL6 can be connected to an anode electrode of the second blue sub-pixel. When one sub-pixel includes only one light-emitting element, the number of the signal wires TL can be reduced by half.

A second electrode 104 can be a cathode electrode that is disposed one for each row and applies a cathode voltage to the light-emitting elements 100 arranged successively in the first direction (the X-axis direction). A plurality of second electrodes 104 can be spaced apart from each other in the second direction (the Y-axis direction). The plurality of second electrodes 104 can be connected to the cathode voltage through a contact electrode 106. Each of the plurality of second electrodes 104 can be electrically connected to the contact electrode 106. However, the embodiment is not necessarily limited thereto, and the second electrode 104 can be configured as one electrode layer without being divided into a plurality of electrodes and can function as a common electrode.

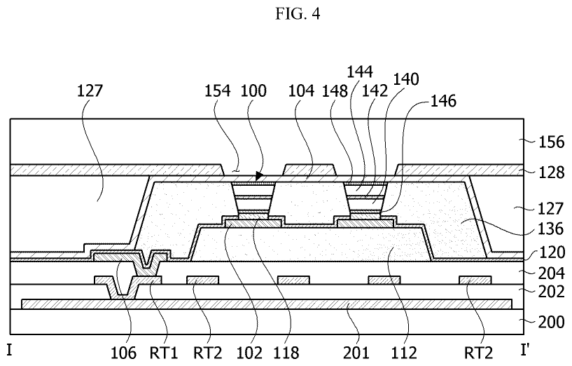

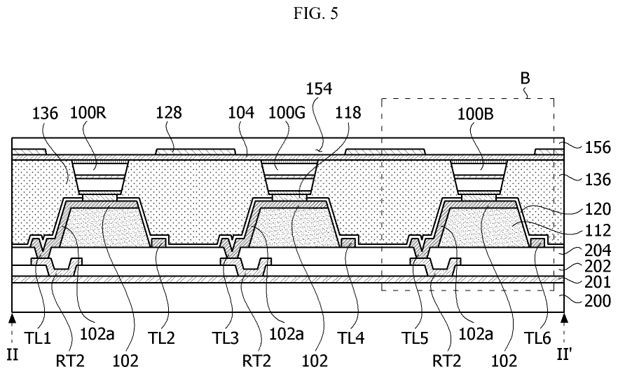

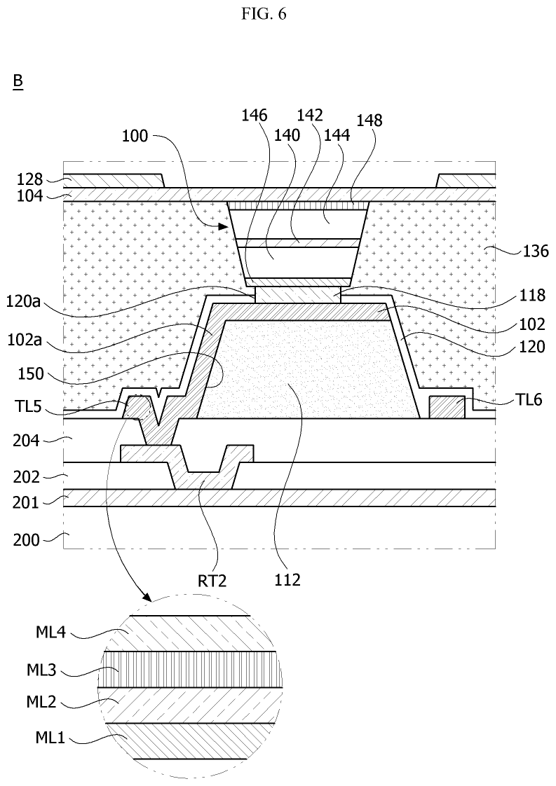

FIG. 4 is a cross-sectional view taken along line I-I′ in FIG. 3. FIG. 5 is a cross-sectional view taken along line II-II′ in FIG. 3. FIG. 6 is an enlarged view of an area ‘B’ in FIG. 5.

Referring to FIGS. 4 to 6, the display device according to an embodiment of the present disclosure includes the plurality of first electrodes 102 and the contact electrode 106 disposed above a substrate 200, the plurality of light-emitting elements 100 disposed on the plurality of first electrodes 102, and a first optical layer 136 disposed between the plurality of light-emitting elements 100. A plurality of light-emitting elements 100 and a first optical layer 136, and a second electrode 104 disposed on the first optical layer 136 is further included.

The substrate 200 can be made of plastic having flexibility. For example, the substrate 200 can be fabricated as a single layer substrate or a multi-layer substrate of materials selected from, but not limited to, polyimide, polyethylene terephthalate, polyethylene naphthalate, polycarbonate, polyethersulfone, polyarylate, polysulfone, and cyclic olefin copolymer. For example, the substrate 200 can be a ceramic substrate or a glass substrate.

A pixel driving circuit 201 can be disposed in the display area on the substrate 200. The pixel driving circuit 201 can include a plurality of thin film transistors using an amorphous silicon semiconductor, a polycrystalline silicon semiconductor, or an oxide semiconductor.

The pixel driving circuit 201 can include at least one driving thin film transistor, at least one switching thin film transistor, and at least one storage capacitor. When the pixel driving circuit 201 includes the plurality of thin film transistors, it can be formed on the substrate 200 by a TFT (thin film transistor) manufacturing process. In an embodiment, the pixel driving circuit 201 can be a collective term for the plurality of thin film transistors electrically connected to the light-emitting element 100.

The pixel driving circuit 201 can be a driving driver manufactured using a metal-oxide-silicon field effect transistor (MOSFET) manufacturing process on a single crystal semiconductor substrate 200. The driving driver can include a plurality of pixel driving circuits to drive the plurality of sub-pixels. When the pixel driving circuit 201 is implemented as the driving driver, an adhesive layer can be disposed on the substrate 200, and then the driving driver can be mounted on the adhesive layer by a transfer process.

A buffer layer 202 covering the pixel driving circuit 201 can be disposed on the substrate 200. The buffer layer 202 can be made of an organic insulating material, e.g., photosensitive photo acryl or photosensitive polyimide, but is not limited thereto.

An insulating layer 204 can be disposed on the buffer layer 202. The insulating layer 204 can be made of an organic insulating material, e.g., photosensitive photo acryl or photosensitive polyimide, but is not limited thereto. Connection wires RT1 and RT2 can be disposed on the buffer layer 202. The connection wires RT1 and RT2 can be connected to the corresponding signal wires TL1 to TL6 or can be connected to the signal wires TL1 to TL6. The connection wires RT1 and RT2 can include a plurality of wire patterns disposed in different layers with one or more insulating layers interposed therebetween. The wire patterns disposed in different layers can be electrically connected through a contact hole penetrating the insulating layers.

A plurality of bank patterns 112 can be disposed on the insulating layer 204. At least one light-emitting element 100 can be disposed above each bank pattern 112. The bank pattern 112 can be formed of an organic insulating material, such as, but not limited to, a photosensitive photo acryl or photosensitive polyimide. The bank pattern 112 can guide a position to which the light-emitting element 100 is to be attached during the transfer process of the light-emitting element 100. The bank pattern 112 can be omitted.

A solder pattern 118 can be disposed on the first electrode 102. The solder pattern 118 can be made of indium (In), tin (Sn), gold (Au), or an alloy thereof, but is not limited thereto.

The plurality of light-emitting elements 100 can be mounted on the respective solder patterns 118.

One pixel can include three colors of light-emitting elements 100. For example, the light-emitting elements 100 can include a red light-emitting element, a green light-emitting element, or a blue light-emitting element. Two light-emitting elements can be mounted in each sub-pixel.

The first optical layer 136 can cover the plurality of light-emitting elements 100 and the plurality of bank patterns 112. Accordingly, the first optical layer 136 can cover between the plurality of light-emitting elements 100 and between the plurality of bank patterns 112. The first optical layer 136 can extend in the first direction X, and can be spaced apart in the second direction Y and separated between the pixel rows.

The first optical layer 136 can include an organic insulating material in which fine metal particles such as titanium dioxide particles are dispersed. Light emitted from the plurality of light-emitting elements 100 can be scattered by the fine metal particles dispersed in the first optical layer 136 and exited to the outside.

The second electrode 104 can be disposed on the plurality of light-emitting elements 100. The second electrode 104 can be commonly connected to the plurality of pixels PXL. The second electrode 104 can be a thin electrode through which light is transmitted. The second electrode 104 can be made of a transparent electrode material, e.g., indium tin oxide (ITO), but is not necessarily limited thereto.

The second electrode 104 can extend in the first direction (the X-axis direction) and can be spaced apart in the second direction (the Y-axis direction). On a plane, each of the plurality of second electrodes 104 can overlap the first optical layer 136 and can cover a plane outside of the first optical layer 136.

A second optical layer 127 can be an organic insulating material above the second electrode 104. The second optical layer 127 can include the same material as the first optical layer 136, (e.g., siloxane). However, the embodiment is not necessarily limited thereto, and the first optical layer 136 and the second optical layer 127 can be formed of the same material or different materials.

The second optical layer 127 can cover a portion above the second electrode 104. That is, the first optical layer 136 and the second optical layer 127 can function as a planarization layer. As a result, a pattern of a black matrix 128 on the second electrode 104 and the second optical layer 127 can be easily formed because there is no step in the plane on which the black matrix 128 is formed. However, the embodiment is not necessarily limited thereto, and the top surfaces of the second optical layer 127 and the second electrode 104 can have different heights.

The black matrix 128 can be an organic insulating material to which a black pigment is added. The second electrode 104 can be in contact with the contact electrode 106 below the black matrix 128. A transmission hole 154 can be formed between the patterns of the black matrix 128, through which light emitted from the light-emitting element 100 exits to the outside. The problem of mixing of light emitted from adjacent light-emitting elements 100 due to the first optical layer 136 can be improved by the black matrix 128.

A cover layer 156 can be an organic insulating material that covers the black matrix 128 and the second electrode 104. The contact electrode 106 can be electrically connected to the first connection wire RT1 disposed therebelow, and the first connection wire RT1 can be connected to the pixel driving circuit 201. Accordingly, a cathode voltage can be applied to the second electrode 104 through the contact electrode 106. The first electrode 102 can be electrically connected to the second connection wire RT2. This will be described later.

The contact electrode 106 and the signal wires TL1 to TL6 can be disposed on the same plane. The pixel driving circuit 201 can be disposed below the contact electrode 106 and the signal wires TL1 to TL6. When the pixel driving circuit 201 is a driving driver, a plurality of driving drivers can be disposed in the display panel.

A passivation layer 120 can expose the contact electrode 106 so that the contact electrode 106 and the second electrode 104 are electrically connected to each other. In addition, the passivation layer 120 can insulate the signal wires TL2 to TL5 from the second electrode 104.

Referring to FIG. 6, the extension portion 102a of the first electrode 102 can extend to one side 150 of the bank pattern 112 and be disposed on the insulating layer 204, and can be electrically connected to the connection wire RT2.

The first electrode 102, the extension portion 102a, the signal wire TL, and/or the connection wires RT1 and RT2 can include a single layer or a multi-layer of metals selected from titanium (Ti), molybdenum (Mo), and aluminum (Al), and the multi-layer includes for example a first layer ML1, a second layer ML2, a third layer ML3, and a fourth layer ML4.

The first layer ML1 and the third layer ML3 can include titanium (Ti) or molybdenum (Mo). The second layer ML2 can include aluminum (Al). The fourth layer ML4 can include a transparent conductive oxide layer, such as indium tin oxide (ITO) or indium zinc oxide (IZO), which has good adhesion to the solder pattern 118, corrosion resistance, and acid resistance.

The first layer ML1, the second layer ML2, the third layer ML3, and the fourth layer ML4 can be deposited sequentially and then patterned by performing a photolithography process and an etching process.

The passivation layer 120 can include an opening hole 120a disposed on the first electrode 102 and the signal wire TL and exposing the solder pattern 118.

The light-emitting element 100 can include a first conductivity type semiconductor layer 140, an active layer 142 disposed on the first conductivity type semiconductor layer 140, and a second conductivity type semiconductor layer 144 disposed on the active layer 142. A first driving electrode 146 can be disposed below the first conductivity type semiconductor layer 140 and a second driving electrode 148 can be disposed above the second conductivity type semiconductor layer 144.

The light-emitting element 100 can be formed on a silicon wafer by using a method such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or sputtering.

The first conductivity type semiconductor layer 140 can be implemented with a compound semiconductor such as a group III-V or a group II-VI and can be doped with a first dopant. The first conductive semiconductor layer 140 can be formed of one or more of the following semiconductor materials: InAlGaN, AlGaAs, GaP, GaAs, GaAsP, and AlGaInP having an empirical formula of Alₓ₁In_{y1}Ga_{(1-x1-y1)}N (0≤x1≤1, 0≤y1≤1, 0≤x1+y1≤1), but is not limited thereto. When the first dopant is an n-type dopant such as Si, Ge, Sn, Se, or Te, the first conductivity type semiconductor layer 140 can be an n-type nitride semiconductor layer. However, when the first dopant is a p-type dopant, the first conductivity type semiconductor layer 140 can be a p-type nitride semiconductor layer.

The active layer 142 is a layer where electrons (or holes) injected through the first conductivity type semiconductor layer 140 and holes (or electrons) injected through the second conductivity type semiconductor layer 144 meet. The active layer 142 can transition to a low energy level as the electrons and the holes recombine, and can generate light having a corresponding wavelength.

The active layer 142 can have any one of a single well structure, a multi-well structure, a single quantum well structure, a multi-quantum well (MQW) structure, a quantum dot structure, or a quantum wire structure, but the structure of the active layer 142 is not limited thereto. The active layer 142 can generate light in a visible wavelength band. For example, the active layer 142 can output light in any one of blue, green, and red wavelength bands.

The second conductivity type semiconductor layer 144 can be disposed on the active layer 142. The second conductivity type semiconductor layer 144 can be implemented with a compound semiconductor such as a group III-V or a group II-VI, and the second conductivity type semiconductor layer 144 can be doped with a second dopant. The second conductivity type semiconductor layer 144 can be formed of a semiconductor material having an empirical formula of Inₓ₂Al_{y2}Ga_{1-x2-y2}N (0≤x2≤1, 0≤y2≤1, 0≤x2+y2≤1) or a material selected from AlInN, AlGaAs, GaP, GaAs, GaAsP, and AlGaInP. When the second dopant is a p-type dopant such as Mg, Zn, Ca, Sr, or Ba, the second conductivity type semiconductor layer 144 doped with the second dopant can be a p-type nitride semiconductor layer. When the second dopant is an n-type dopant, the second conductivity type semiconductor layer 144 can be an n-type nitride semiconductor layer.

Although the light-emitting element has been described as having a vertical structure with driving electrodes 146 and 148 disposed at the upper and lower portions of the light-emitting structure in the embodiments, the light-emitting element can also have a lateral structure or a flip chip structure in addition to the vertical structure.

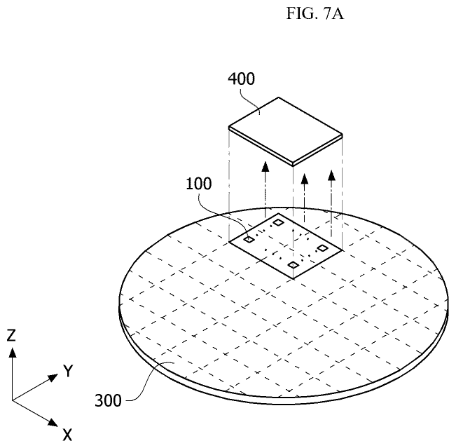

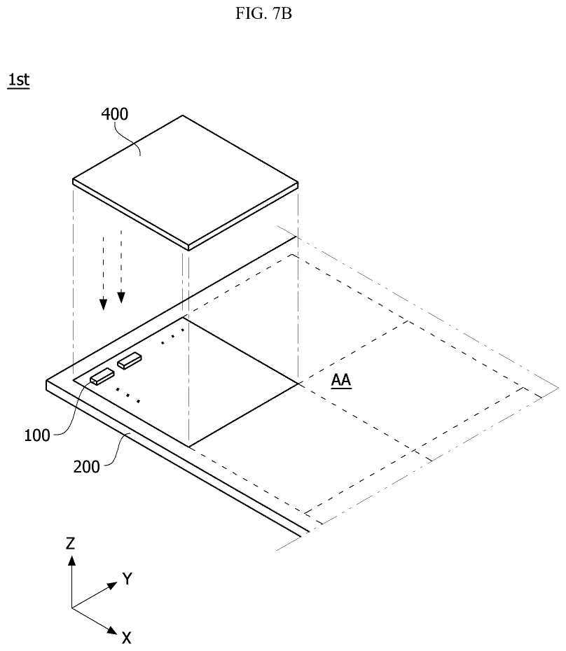

Hereinafter, a process of picking up and transferring a plurality of light-emitting elements constituting the display device from a growth substrate and transferring them to a transfer substrate using a stamp according to one embodiment of the present disclosure will be described with reference to FIGS. 7A and 7B.

FIGS. 7A and 7B are perspective views illustrating a process for picking up and transferring the light-emitting elements using a stamp according to one embodiment of the present disclosure.

Referring to FIGS. 7A and 7B, in order to transfer a plurality of light-emitting elements constituting the display device, there can be provided a growth substrate 300 having a plurality of light-emitting elements 100, a light-emitting element transfer stamp 400 for picking up and transferring the plurality of light-emitting elements 100, and a substrate 200 on which the plurality of light-emitting elements 100 are transferred to form a display panel.

The growth substrate 300 can be used as a base substrate for growing the light-emitting element 100, which is an LED chip, and can be made of, but not limited to, silicon (Si), sapphire (Al₂O₃), silicon carbide (SiC), gallium arsenide (GaAs), gallium nitride (GaN), gallium phosphide (GaP), indium phosphide (InP), zinc oxide (ZnO), spinel (MgAl₂O₄), magnesium oxide (MgO), lithium metaaluminate (LiAlO₂), aluminum nitride (AlN), and lithiumgallate (LiGaO₂).

On the growth substrate 300, a plurality of micro light-emitting elements 100 can be grown.

The light-emitting element 100 is a semiconductor device that emits light energy of various wavelengths by applying an electrical signal using the properties of a compound semiconductor. The light-emitting element 100 can be configured to have a thickness as small as a few microns.

The plurality of light-emitting elements 100 are arranged side-by-side in one direction on the growth substrate 300. A gap between adjacent light-emitting elements 100 is set to have a minimum distance in the process. For example, to reduce the manufacturing cost of the growth substrate 300, it is desirable to integrate many light-emitting elements 100 within a small growth substrate 300.

The light-emitting element transfer stamp 400 is used as a transfer means for transferring a plurality of light-emitting elements 100 from the growth substrate 300 to the substrate 200. The light-emitting element transfer stamp 400 selectively picks up the light-emitting element 100 from the growth substrate 300. The light-emitting element transfer stamp 400 selectively picks up light-emitting elements 100 at predetermined locations and transfers them to respective corresponding pixels on the substrate 200.

The substrate 200 is a substrate constituting the display device and has a plurality of pixels arranged thereon. An area where the plurality of pixels is arranged can be defined as an active area. At least one light-emitting element 100 is finally allocated to each of the plurality of pixels. The signal wires and electrodes for applying the driving signals to the light-emitting elements 100 can be arranged on the substrate 200. When implemented in an AM (active matrix) method, the substrate 200 can further include thin film transistors allocated to each pixel.

Referring to FIG. 7B, the light-emitting elements 100 transferred to neighboring pixels are arranged to be spaced apart by a predetermined spacing. The spacing between neighboring light-emitting elements 100 of the light-emitting elements 100 transferred to the substrate 200 can be appropriately selected in consideration of display characteristics, element arrangement, and the like.

The substrate 200 can be prepared to have a relatively larger size than the light-emitting element transfer stamp 400.

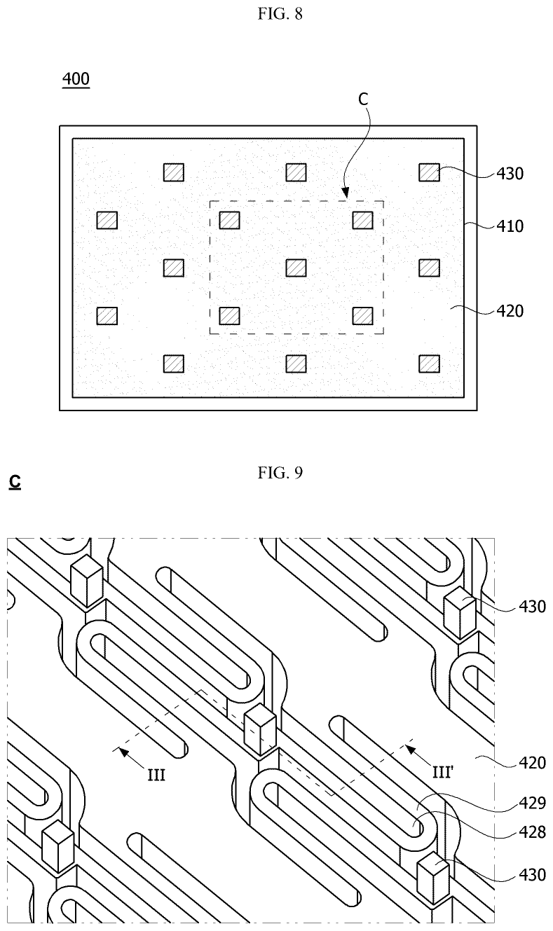

Hereinafter, a stamp structure for transferring the light-emitting elements according to one embodiment of the present disclosure will be described with reference to FIGS. 8 to 10.

FIG. 8 is a plan view illustrating a stamp according to one embodiment of the present disclosure, FIG. 9 is an enlarged perspective view of an area C of FIG. 8, and FIG. 10 is a cross-sectional view taken along line III-III′ in FIG. 9.

Referring to FIGS. 8 to 10, the light-emitting element transfer stamp 400 according to one embodiment of the present disclosure includes a stamp substrate (sometimes also referred to as “a first substrate”) 410, an elastic part 420 disposed on the stamp substrate 410, a plurality of pickup portions 430 protruding from the top surface of the elastic part 420, and a damper part 440 connected to the elastic part 420.

As the stamp substrate 410 constituting the stamp 400, a quartz substrate, a sapphire substrate, or a silicon substrate can be used. However, the present disclosure is not necessarily limited thereto.

A spring tensioning part 412 with a certain space is formed between the stamp substrate 410 and the elastic part 420.

The stamp substrate 410 and the elastic part 420 can be bonded together or can be integrally formed. It is not limited thereto.

The spring tensioning part 412 with a certain space can provide a space for the elastic part 420 to be tensioned when the pickup portion 430 picks up the light-emitting element 100 on the growth substrate 300 (see FIG. 7A). If the spring tensioning part 412 were not present, the elastic part 420 would not be able to be tensioned when the light-emitting element 100 is picked up.

The elastic part 420 includes a plurality of leaf springs 429 separated by elastic spacing portions 428 positioned at regular intervals in the horizontal direction, and these leaf springs 429 can have elastic force with each other. In this case, the leaf spring 429 can include a single leaf spring, a double leaf spring, or the like. However, the elastic part 420 is not limited to the leaf spring and can have various types of spring shapes applied thereto. For example, a coil spring such as a compression coil spring, a tension coil spring, or a torsion coil spring can be applied. In addition, various other types of spring systems capable of absorbing vibration or elastic energy to provide a buffering effect can be applied.

The elastic spacing portion 428 of the elastic part 420 is in contact with the spring tensioning part 412.

When the elastic part 420 is tensioned due to the pickup of a light-emitting element chip by the pickup portion 430, the elastic energy stored in the elastic part 420 is converted into kinetic energy after the light-emitting element chip is picked up, causing the spring to vibrate.

Assuming that there is no energy loss, according to the law of conservation of energy, elastic energy is continuously converted into kinetic energy, resulting in continuous vibration.

The plurality of pickup portions 430 protrude in a vertical direction from the elastic part 420. The pickup portions 430 can be integrally formed with the elastic part 420. However, the present disclosure is not necessarily limited thereto. For example, the plurality of leaf springs 429 can be formed around the plurality of pickup portions 430.

Referring to FIG. 10, the damper part 440 is connected to the elastic part 420 through a damper insertion groove 414 formed inside the stamp substrate 410. The damper insertion groove 414 can extend not only within the stamp substrate 410, but also into the elastic part 420.

The damper part 440 includes a damper extension portion 442 is located on the bottom surface of the stamp substrate 410, and includes a damper extension portion 442 that extends from the damper part 440, and is connected to the elastic part 420 within the damper insertion groove 414 formed inside the stamp substrate 410.

The damper part 440 can contain a polymer having viscoelastic properties, such as PDMS (Polydimethylsiloxane) or polyurethane, and a fluid such as water or oil. In particular, a polymer having viscoelastic properties and a fluid such as water or oil have excellent performance in absorbing vibration.

In addition, the damper part 440 can contain a viscoelastic material or a viscoelastic material having photosensitive properties.

The viscoelastic material can include acrylic-based, butyl-based, polypropylene-based, silicone-based, and urethane-based rubber. However, it is not limited thereto.

The damper part 440 can serve to dampen spring vibration by absorbing or dissipating the elastic energy and kinetic energy that generate the spring vibration.

Thus, the damping ratio of the spring vibration of the elastic part 420 can be adjusted by the stiffness design of the damper part 440, thereby maximizing the transfer yield of the light-emitting element chip of the stamp 400.

The damper extension portion 442 is connected to the elastic part 420 to dampen the vibration of the elastic part 420 by absorbing the vibration generated from the elastic part 420 as the elastic part 420 is tensioned simultaneously with the pickup of the light-emitting element.

In addition, the damper extension portion 442 dampens the vibration of the elastic part 420 that occurs during the movement of the stamp 400 after the light-emitting element is picked up.

Hereinafter, a process of transferring a light-emitting element using a light-emitting element transfer stamp according to one embodiment of the present disclosure will be described.

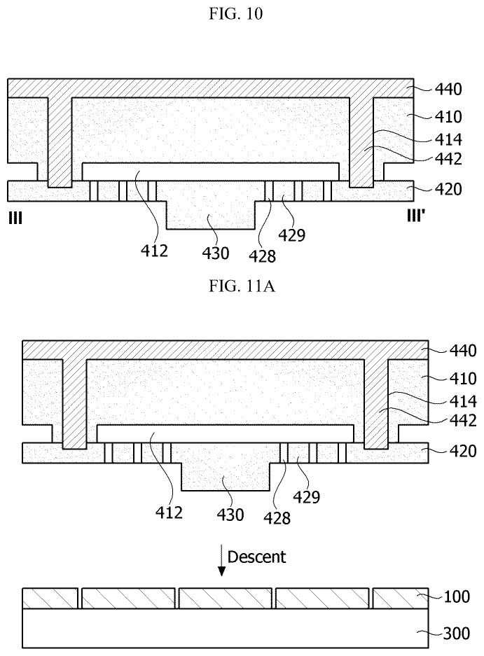

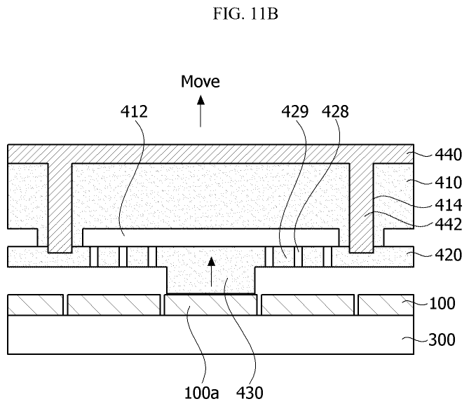

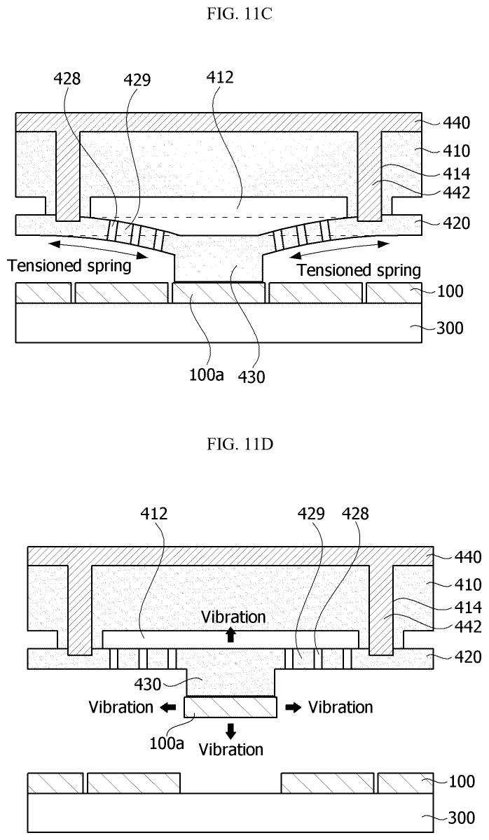

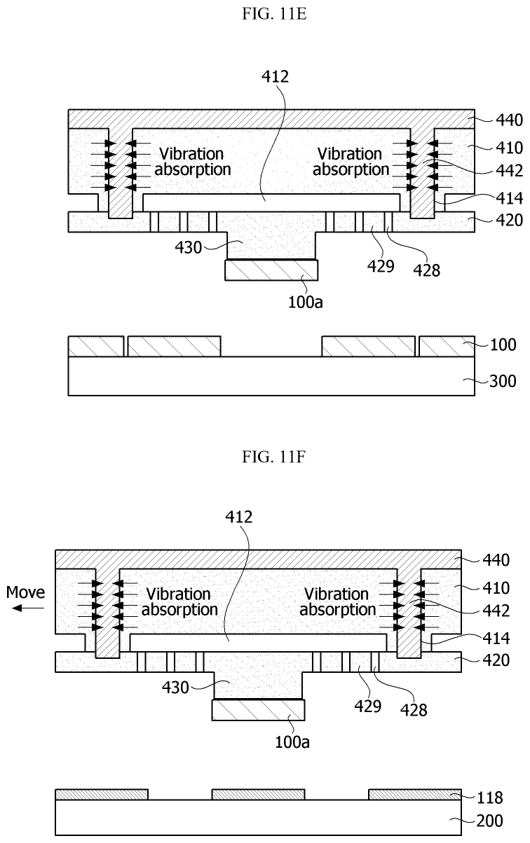

FIGS. 11A to 11F are cross-sectional views illustrating the process of picking up and transferring a light-emitting element using a stamp according to one embodiment of the present disclosure.

Referring to FIG. 11A, the stamp 400 including the stamp substrate 410, the elastic part 420 disposed on the stamp substrate 410, the plurality of pickup portions 430 protruding from the top surface of the elastic part 420, and the damper part 440 connected to the elastic part 420 is prepared.

Next, the stamp 400 is disposed above the growth substrate 300 on which the plurality of light-emitting elements 100 are formed.

In this case, the pickup portions 430 of the stamp 400 are positioned to correspond to the plurality of light-emitting elements 100 formed on the growth substrate 300.

Next, referring to FIG. 11B, the stamp 400 is lowered toward the growth substrate 300 to bring the pickup portion 430 into contact with the top surface of a light-emitting element 100a positioned corresponding the pickup portion 430.

Next, referring to FIG. 11C, in a state where the pickup portion 430 is in contact with the light-emitting element 100a on the growth substrate 300, the light-emitting element 100a is picked up and moved upward.

In this case, the light-emitting element 100a on the growth substrate 300 has been separated by a separate method such as laser irradiation or the like, so that the stamp 400 can pick up the light-emitting element 10 by simply performing a pickup operation.

When the light-emitting element 100a is picked up and moved upward by the pickup portion 430, the elastic part 420 is tensioned toward the growth substrate 300 due to the weight of the light-emitting element 100a.

In this case, as the elastic part 420 is tensioned, the spring tensioning part 412 between the stamp substrate 410 and the elastic part 420 widens toward the growth substrate 300.

In addition, the leaf spring 429 of the elastic part 420 is also tensioned, causing vibration.

The leaf spring 429 can include a single leaf spring, a double leaf spring, or the like. However, the elastic part 420 is not limited to the leaf spring, and various types of spring shapes can be applied. For example, a coil spring such as a compression coil spring, a tension coil spring, or a torsion coil spring can be applied. In addition, various other types of spring systems capable of absorbing vibration or elastic energy to provide a buffering effect can be applied.

Next, referring to FIG. 11D, when the elastic part 420 is tensioned due to the pickup of the light-emitting element 100a from the growth substrate 300 by the pickup portion 430, the elastic energy stored in the elastic part 420 is converted into kinetic energy after the light-emitting element 100a is picked up, causing the elastic part 420 and the pickup portion 430 to vibrate vertically and horizontally.

In this case, as shown in FIG. 11E, the damper part 440 connected to the elastic part 420 in the stamp substrate 410 serves to dampen the spring vibration by absorbing or dissipating the elastic energy and kinetic energy that generate the spring vibration from the elastic part 420. In particular, the damper extension portion 442 is connected to the elastic part 420 through the damper insertion groove 414 formed inside the stamp substrate 410 to absorb or dissipate the vibration generated in the elastic part 420.

Next, referring to FIG. 11F, the stamp 400 that has picked up the light-emitting element 100a through the pickup portion 430 is moved to the substrate 200 and aligned above a predetermined pixel area of the substrate 200.

Subsequently, as shown in FIG. 11F, the light-emitting element 100a is transferred onto the solder pattern 118 located in the predetermined pixel area of the substrate 200.

In this case, when the light-emitting element 100a is transferred onto the substrate 200, lowering the temperature by stopping the heat application (heat off) causes the thermally expanded pickup portion 430 to contract, reducing the contact area between the pickup portion 430 and the light-emitting element 100a, thereby decreasing the adhesive force. As a result, the light-emitting element 100a can be easily transferred onto the substrate 200 from the pickup portion 430.

As such, the damper part 440 connected to the elastic part 420 in the stamp substrate 410 serves to dampen the spring vibration by absorbing or dissipating the elastic energy and kinetic energy that generate the spring vibration from the elastic part 420.

In particular, the damper extension portion 442 absorbs or dissipates the vibration generated in the elastic part 420 through the damper insertion groove 414 formed within the stamp substrate 410.

Accordingly, when the light-emitting element 100a is picked up by the pickup portion 440, the vibration generated in the elastic part 420 is absorbed by the damper part 440 to dampen the spring vibration, thereby enabling the light-emitting element 100a to be accurately transferred onto the predetermined pixel area of the substrate 200.

In addition, the damping ratio of the spring vibration of the elastic part 420 can be adjusted through the stiffness design of the damper part 440, thereby increasing the transfer accuracy of the light-emitting element chip by the stamp 400 and maximizing the transfer yield of the light-emitting element chip.

FIG. 12 is a diagram illustrating an example of the change in amplitude over time during the pickup of a light-emitting element using a stamp having an elastic part and a damper part according to one embodiment of the present disclosure, and a stamp having only a spring.

Referring to FIG. 12, in the case where the damper part 440 is not provided in the stamp 400, it can be observed that it can be seen that the amplitude is continuously maintained constant even after a time elapses when the light emitting device is picked up by the stamp, as shown by a curve E. This indicates that the vibration generated in the spring provided in the stamp during the pickup of the light-emitting element can be continuously maintained without being damped.

On the other hand, in the case where the damper part 440 is coupled to the stamp 400, it can be observed that the vibration generated in the elastic part 420 when the light-emitting element is picked up by the stamp 400 is gradually dampened as time increases, as shown by a curve D.

This is because the damper part 440 serves to absorb and dampen the vibration generated in the elastic part 420.

Hereinafter, a method for fabricating the light-emitting element transfer stamp according to one embodiment of the present disclosure will be described.

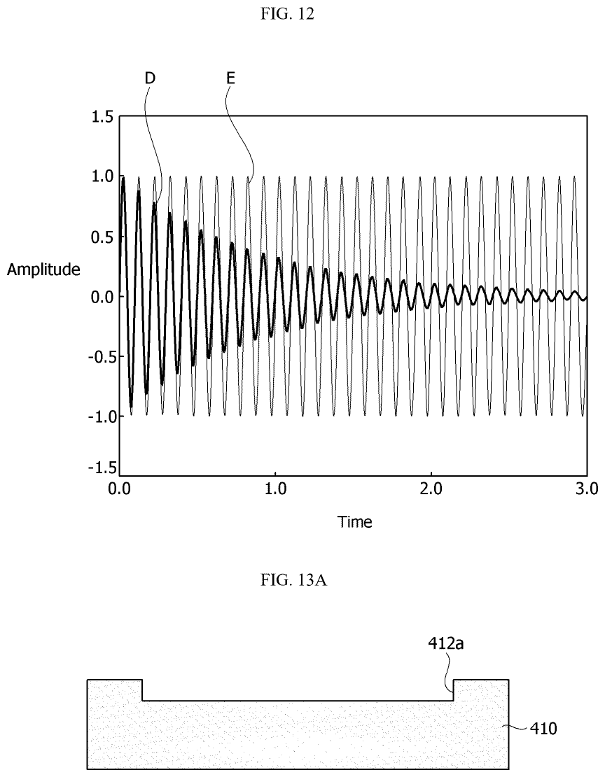

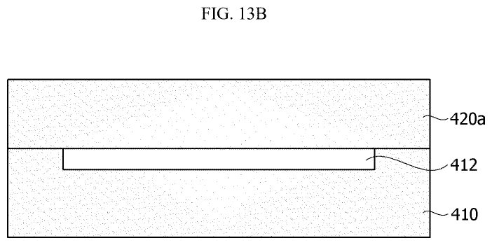

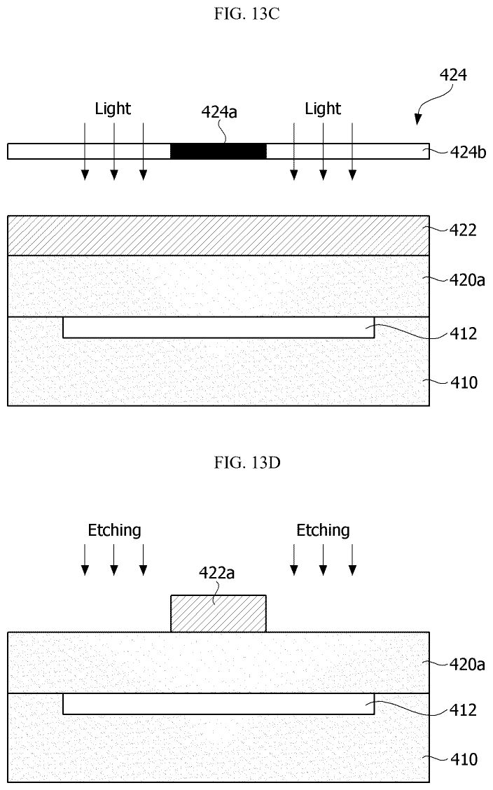

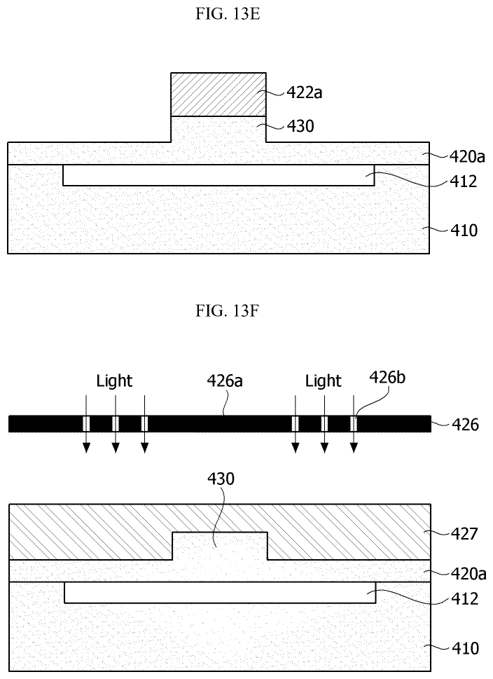

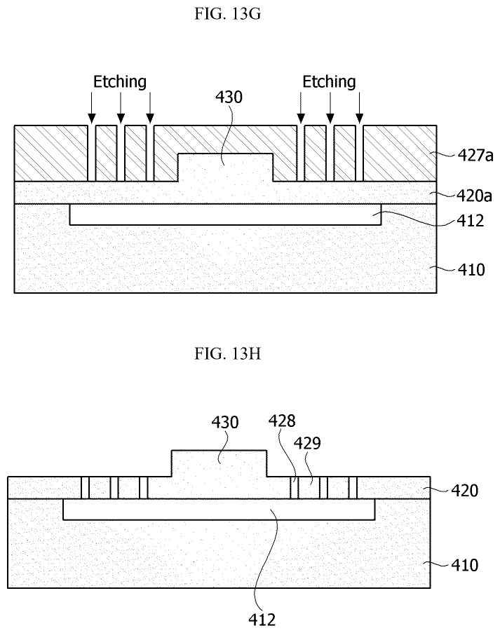

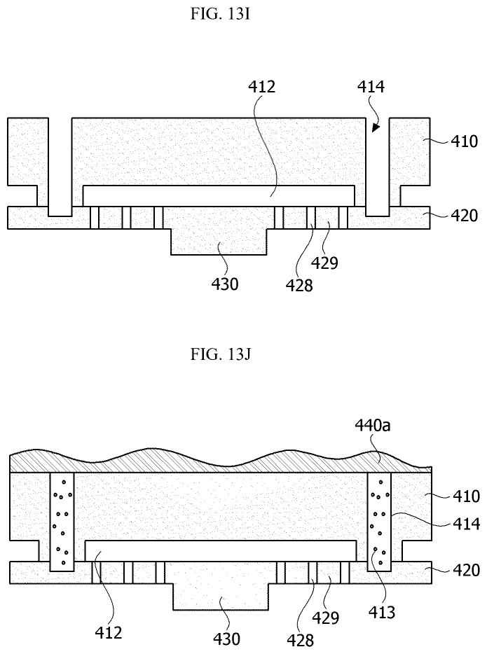

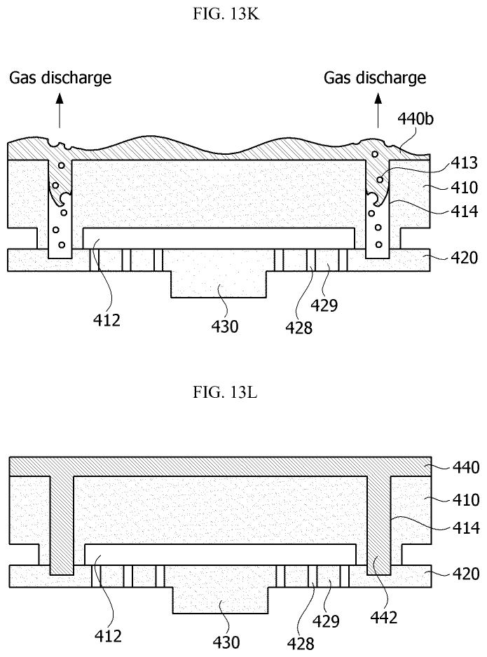

FIGS. 13A to 13L are cross-sectional views of a stamp fabricating process according to one embodiment of the present disclosure.

Referring to FIG. 13A, the stamp substrate 410 is prepared, and a concave groove 412a having a certain space is formed on the stamp substrate 410 by a mask process using a photolithography technique. A quartz substrate, a sapphire substrate, or a silicon substrate can be used as the stamp substrate 410. However, it is not necessarily limited thereto.

Next, referring to FIG. 13B, a spring substrate 420a for use as the elastic part is disposed on the stamp substrate 410 and bonded to it. In this case, the spring substrate 420a can be made of the same material as the stamp substrate 410. However, it is not limited thereto.

A quartz substrate, a sapphire substrate, or a silicon substrate can be used as the spring substrate 420a. However, it is not necessarily limited thereto.

Alternatively, the spring substrate 420a can be integrally formed with the stamp substrate 410.

Moreover, as the spring substrate 420a is bonded and joined with the stamp substrate 410, the spring tensioning part 412 is formed with a certain space therebetween. In this case, the spring tensioning part 412 can be formed by covering the concave groove 412a with the spring substrate 420a.

The spring tensioning part 412 with a certain space can provide a space for the elastic part 420 to be tensioned when the pickup portion 430 picks up the light-emitting element 100 on the growth substrate 300 (see FIG. 7A). If the spring tensioning part 412 were not present, the elastic part 420 would not be able to be tensioned when the light-emitting element 100 is picked up.

Next, referring to FIG. 13C, a first photoresist layer 422 is applied on the spring substrate 420a, and a first photomask 424 is disposed at a certain distance above the first photoresist layer. In this case, the first photomask 424 includes a light blocking portion 424a and a transmission portion 424b.

Next, light is irradiated onto the top of the first photoresist layer 422 using the first photomask 424 as a mask.

Referring to FIG. 13D, the exposed first photoresist layer 422 is then selectively removed through a development process to form a first photoresist layer pattern 422a.

Next, referring to FIG. 13E, using the first photoresist layer pattern 422a as a mask, the spring substrate 420a therebelow is etched to a certain thickness to form the pickup portion 430 in an area located below the first photoresist layer pattern 422a.

The plurality of pickup portions 430 can be formed on the entire surface of the spring substrate 420a at regular intervals.

The plurality of pickup portions 430 can protrude from the elastic part 420 in the vertical direction. The pickup portions 430 can be integrally formed with the elastic part 420. However, the present disclosure is not necessarily limited thereto.

Next, referring to FIG. 13F, the first photoresist layer pattern 422a is removed, and then a second photoresist layer 427 is applied onto the entire surface of the spring substrate 420a including the pickup portion 430, and a second photomask 426 is disposed at a certain distance above the second photoresist layer. In this case, the second photomask 426 can include a light blocking portion 426a and a transmission portion 426b.

Next, referring to FIG. 13G, the second photoresist layer 427 is exposed using the second photomask 426 as a mask, and then selectively removed through a development process, thereby forming a second photoresist layer pattern 427a.

Next, referring to FIG. 13H, the spring substrate 420a is selectively etched using the second photoresist layer pattern 427a as a mask to form the plurality of leaf springs 429 with the elastic spacing portion 428 therebetween, and then the remaining second photoresist layer pattern 427a is removed. In this case, the plurality of leaf springs 429 can be formed with the pickup unit 430 interposed therebetween.

The plurality of leaf springs 429 and the elastic spacing portion 428 are in contact with the spring tensioning part 412.

In this case, the elastic part 420 includes the plurality of leaf springs 429 separated by the elastic spacing portions 428 positioned at regular intervals in the horizontal direction of the stamp substrate 410. The leaf springs 429 have elastic force with each other, and are configured in a plate shape. The elastic part 420 can be integrally formed with the stamp substrate 410. However, it is not limited thereto.

In this case, the leaf spring 429 can include a single leaf spring, a double leaf spring, or the like. However, the elastic part 420 is not limited to the leaf spring, and various types of spring shapes can be applied. For example, a coil spring such as a compression coil spring, a tension coil spring, or a torsion coil spring can be applied. In addition, various other types of spring systems capable of absorbing vibration or elastic energy to provide a buffering effect can be applied.

When the elastic part 420 is tensioned due to the pickup of the light-emitting element chip by the pickup portion 430, the elastic energy stored in the elastic part 420 is converted into kinetic energy after the light-emitting element chip is picked up, causing the spring to vibrate.

Assuming that there is no energy loss, according to the law of conservation of energy, elastic energy is continuously converted into kinetic energy, resulting in continuous vibration.

Next, referring to FIG. 13I, the plurality of damper insertion grooves 414 are formed in the stamp substrate 410 through a micro-electromechanical systems (MEM) process.

In this case, the MEM process can employ the same process used to form the pickup portion 430 and leaf spring 429 as described above. However, it is not necessarily limited thereto.

A third photoresist is applied onto the stamp substrate 410 and then selectively removed through a mask process using a photolithography technique.

Subsequently, using the selectively removed third photoresist as a mask, the stamp substrate 410 is etched to form the plurality of damper insertion grooves 414 within the stamp substrate 410. In this case, the plurality of damper insertion grooves 414 can extend into the elastic part 420.

Next, referring to FIG. 13J, a polymer material 440a in a liquid state is spin-coated on the stamp substrate 410. In this case, the polymer material 440a in a liquid state is not coated inside the damper insertion groove 414 but is coated only on the top of the stamp substrate 410. This is because the damper insertion groove 414 of the stamp substrate 410 is filled with trapped air, which prevents the liquid polymer from penetrating into the damper insertion groove 414.

The polymer 440a of the liquid material can include a polymer having viscoelastic properties, such as PDMS or polyurethane, and a fluid such as water or oil. In particular, a polymer having viscoelastic properties and a fluid such as water or oil have excellent performance in absorbing vibration.

The viscoelastic material can include acrylic-based, butyl-based, polypropylene-based, silicone-based, and urethane-based rubber. However, it is not limited thereto.

Next, referring to FIG. 13K, a gas 413 filled within the damper insertion groove 414 of the stamp substrate 410 is removed by performing a degassing process. In this case, as the gas 413 is removed, the liquid polymer material 440a is introduced into and filled within the damper insertion groove 414 from which the gas has been removed.

Next, referring to FIG. 13L, a relaxation and baking process is performed on the polymer material 440a filled within the damper insertion groove 414 to form the damper part 440.

In this case, the damper part 440 is disposed on the rear surface of the stamp substrate 410, and the damper extension portion 442 extending from the damper part 440 is positioned within the damper insertion groove 414 to be connected to the elastic part 420. This completes the process of forming the damper part 440 that is connected to the elastic part 420 provided on the stamp substrate 410.

Hereinafter, the light-emitting element transfer stamps according to second to fifth embodiments of the present disclosure will be described.

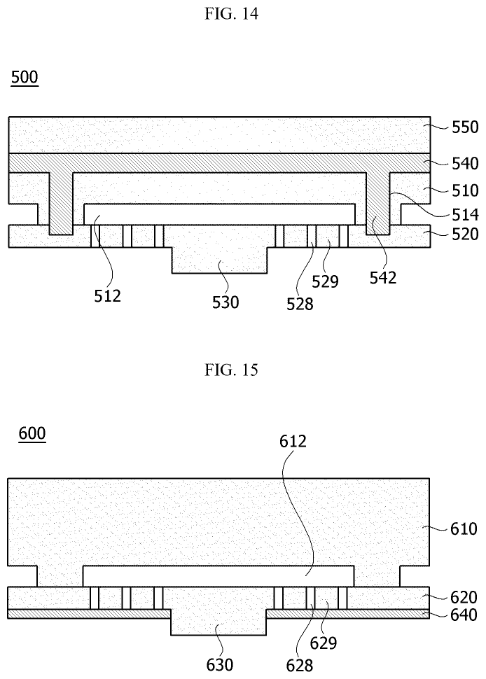

FIG. 14 is a diagram illustrating a stamp according to the second embodiment of the present disclosure.

Referring to FIG. 14, a stamp 500 according to the second embodiment of the present disclosure includes a first stamp substrate 510, an elastic part 520 provided on the first stamp substrate 510, a plurality of pickup portions 530 protruding from the top surface of the elastic part 520, a damper part 540 connected to the elastic part 520, and a second stamp substrate 550 disposed on top of the damper part 540.

As the first and second stamp substrates 510 and 550 constituting the stamp 500, a quartz substrate, a sapphire substrate, or a silicon substrate can be used. However, it is not necessarily limited thereto.

A spring tensioning part 512 with a certain space is formed between the first stamp substrate 510 and the elastic part 520.

The spring tensioning part 512 with a certain space can provide a space for the elastic part 520 to be tensioned when the pickup portion 530 picks up the light-emitting element 100 (see FIG. 7A) on the growth substrate 300 (see FIG. 7A). If the spring tensioning part 512 were not present, the elastic part 520 would not be able to be tensioned when the light-emitting element 100 is picked up.

The elastic part 520 includes a plurality of leaf springs 529 separated by an elastic spacing portion 528 positioned at regular intervals in the horizontal direction of the first stamp substrate 510, and these leaf springs 429 can have elastic force with each other and are configured in a plate shape. The elastic part 520 can be integrally formed with the stamp substrate 510. However, it is not limited thereto.

When the elastic part 520 is tensioned due to the pickup of the light-emitting element chip by the pickup portion 530, the elastic energy stored in the elastic part 520 is converted into kinetic energy after the light-emitting element chip is picked up, causing the spring to vibrate.

Assuming that there is no energy loss, according to the law of conservation of energy, elastic energy is continuously converted into kinetic energy, resulting in continuous vibration.

The plurality of pickup portions 530 protrude from the elastic part 520 in the vertical direction. The pickup portions 530 can be integrally formed with the elastic part 520. However, the present disclosure is not necessarily limited thereto.

The damper part 540 is connected to the elastic part 520 through a damper insertion groove 514 formed inside the first stamp substrate 510.

The damper part 540 includes a damper extension portion 542 that is located on the bottom surface of the first stamp substrate 510, extends from the damper part 540, and is disposed within the damper insertion groove 514 to be connected to the elastic part 520.

The damper part 540 can contain a polymer having viscoelastic properties, such as PDMS or polyurethane, and a fluid such as water or oil. In particular, a polymer having viscoelastic properties and a fluid such as water or oil have excellent performance in absorbing vibration.

In addition, the damper part 540 can contain a viscoelastic material or a viscoelastic material having photosensitive properties.

The viscoelastic material can include acrylic-based, butyl-based, polypropylene-based, silicone-based, and urethane-based rubber. However, it is not limited thereto.

The damper part 540 can serve to dampen spring vibration by absorbing or dissipating the elastic energy and kinetic energy that generate the spring vibration.

Thus, the damping ratio of the spring vibration of the elastic part 520 can be adjusted through the stiffness design of the damper part 540, thereby maximizing the transfer yield of the light-emitting element chip of the stamp 500.

The damper extension portion 542 is connected to the elastic part 520 to dampen the vibration of the elastic part 520 by absorbing the vibration generated from the elastic part 520 as the elastic part 520 is tensioned simultaneously with the pickup of the light-emitting element.

In addition, the damper extension portion 542 dampens the vibration of the elastic part 520 that occurs during the movement of the stamp 500 after the light-emitting element is picked up.

FIG. 15 is a diagram illustrating a stamp according to the third embodiment of the present disclosure.

Referring to FIG. 15, a stamp 600 according to the third embodiment of the present disclosure includes a stamp substrate 610, an elastic part 620 disposed on the stamp substrate 610, a plurality of pickup portions 630 protruding from the top surface of the elastic part 620, and a damper part 640 disposed on top of the elastic part 620.

As the stamp substrate 610, a quartz substrate, a sapphire substrate, or a silicon substrate can be used. However, the present disclosure is not necessarily limited thereto.

A spring tensioning part 612 with a certain space is formed between the stamp substrate 610 and the elastic part 620.

The spring tensioning part 612 with a certain space can provide a space for the elastic part 620 to be tensioned when the pickup portion 630 picks up the light-emitting element 100 (see FIG. 7A) on the growth substrate 300 (see FIG. 7A). If the spring tensioning part 612 were not present, the elastic part 620 would not be able to be tensioned when the light-emitting element 100 is picked up.

The elastic part 620 includes a plurality of leaf springs 629 separated by an elastic spacing portion 628 positioned at regular intervals in the horizontal direction of the stamp substrate 610, and these leaf springs 629 can have elastic force with each other and are configured in a plate shape. The elastic part 620 can be integrally formed with the stamp substrate 610. However, it is not limited thereto.

When the elastic part 620 is tensioned due to the pickup of the light-emitting element chip by the pickup portion 630, the elastic energy stored in the elastic part 620 is converted into kinetic energy after the light-emitting element chip is picked up, causing the spring to vibrate.

Assuming that there is no energy loss, according to the law of conservation of energy, elastic energy is continuously converted into kinetic energy, resulting in continuous vibration.

The plurality of pickup portions 630 protrude in the vertical direction from the elastic part 620. The pickup portions 630 can be integrally formed with the elastic part 620. However, the present disclosure is not necessarily limited thereto.

The damper part 640 is disposed on top of the elastic part 620 and is in contact with the elastic spacing portion 628 of the elastic part 620. Further, the damper part 640 is in contact with the side surface of the pickup portion 630.

The damper part 640 can contain a polymer having viscoelastic properties, such as PDMS or polyurethane, and a fluid such as water or oil. In particular, a polymer having viscoelastic properties and a fluid such as water or oil have excellent performance in absorbing vibration.

In addition, the damper part 540 can contain a viscoelastic material or a viscoelastic material having photosensitive properties.

The viscoelastic material can include acrylic-based, butyl-based, polypropylene-based, silicone-based, and urethane-based rubber. However, it is not limited thereto.

The damper part 640 can serve to dampen spring vibration by absorbing or dissipating the elastic energy and kinetic energy that generate the spring vibration.

Thus, the damping ratio of the spring vibration of the elastic part 620 can be adjusted through the stiffness design of the damper part 640, thereby maximizing the transfer yield of the light-emitting element chip of the stamp 600.

FIG. 16 is a diagram illustrating a stamp according to the fourth embodiment of the present disclosure.

Referring to FIG. 16, a stamp 700 according to the fourth embodiment of the present disclosure includes a stamp substrate 710, an elastic part 720 provided on the stamp substrate 710, a plurality of pickup portions 730 protruding from the top surface of the elastic part 720, a first damper part 742 disposed on top of the elastic part 720, and a second damper part 744 disposed between the stamp substrate 710 and the elastic part 720.

As the stamp substrate 710 constituting the stamp 700, a quartz substrate, a sapphire substrate, or a silicon substrate can be used. However, the present disclosure is not necessarily limited thereto.

A spring tensioning part 712 with a certain space is formed between the stamp substrate 710 and the elastic part 720.

The spring tensioning part 712 with a certain space can provide a space for the elastic part 720 to be tensioned when the pickup portion 730 picks up the light-emitting element 100 (see FIG. 7A) on the growth substrate 300 (see FIG. 7A). If the spring tensioning part 712 were not present, the elastic part 720 would not be able to be tensioned when the light-emitting element 100 is picked up.

The elastic part 720 includes a plurality of leaf springs 729 separated by an elastic spacing portion 728 positioned at regular intervals in the horizontal direction of the stamp substrate 710, and these leaf springs 729 can have elastic force with each other and are configured in a plate shape. The elastic part 720 can be integrally formed with the stamp substrate 710. However, it is not limited thereto.

When the elastic part 720 is tensioned due to the pickup of the light-emitting element chip by the pickup portion 730, the elastic energy stored in the elastic part 720 is converted into kinetic energy after the light-emitting element chip is picked up, causing the spring to vibrate.

Assuming that there is no energy loss, according to the law of conservation of energy, elastic energy is continuously converted into kinetic energy, resulting in continuous vibration.

The plurality of pickup portions 730 protrude in the vertical direction from the elastic part 720. The pickup portions 730 can be integrally formed with the elastic part 720. However, the present disclosure is not necessarily limited thereto.

The first damper part 742 is disposed on top of the elastic part 720 and is in contact with the elastic spacing portion 728 of the elastic part 720. Further, the first damper part 742 is in contact with the side surface of the pickup portion 730.

The second damper part 744 is disposed on the inner surface of the spring tensioning part 712 between the stamp substrate 710 and the elastic part 720.

The first and second damper parts 742 and 744 can contain a polymer having viscoelastic properties, such as PDMS or polyurethane, and a fluid such as water or oil. In particular, a polymer having viscoelastic properties and a fluid such as water or oil have excellent performance in absorbing vibration.

In addition, the first and second damper parts 742 and 744 can contain a viscoelastic material or a viscoelastic material having photosensitive properties.

The viscoelastic material can include acrylic-based, butyl-based, polypropylene-based, silicone-based, and urethane-based rubber. However, it is not limited thereto.

The first and second damper parts 742 and 744 can serve to dampen spring vibration by absorbing or dissipating the elastic energy and kinetic energy that generate the spring vibration.

Thus, the damping ratio of the spring vibration of the elastic part 720 can be adjusted through the stiffness design of the first and second damper parts 742 and 744, thereby maximizing the transfer yield of the light-emitting element chip of the stamp 700.

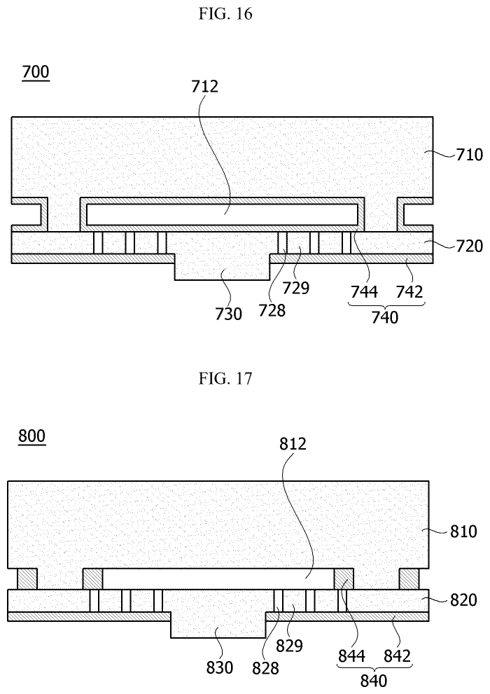

FIG. 17 is a diagram illustrating a stamp according to the fifth embodiment of the present disclosure.

Referring to FIG. 17, a stamp 800 according to the fifth embodiment of the present disclosure includes a stamp substrate 810, an elastic part 820 provided on the stamp substrate 810, a plurality of pickup portions 830 protruding from the top surface of the elastic part 820, a first damper part 842 disposed on top of the elastic part 820, and a second damper part 844 disposed between the stamp substrate 810 and the elastic part 820.

As the stamp substrate 810, a quartz substrate, a sapphire substrate, or a silicon substrate can be used. However, it is not necessarily limited thereto.

A spring tensioning part 812 with a certain space is formed between the stamp substrate 810 and the elastic part 820.

The spring tensioning part 812 with a certain space can provide a space for the elastic part 820 to be tensioned when the pickup portion 830 picks up the light-emitting element 100 (see FIG. 7A) on the growth substrate 300 (see FIG. 7A). If the spring tensioning part 812 were not present, the elastic part 820 would not be able to be tensioned when the light-emitting element 100 is picked up.

The elastic part 820 includes a plurality of leaf springs 829 separated by an elastic spacing portion 828 positioned at regular intervals in the horizontal direction of the stamp substrate 810, and these leaf springs 829 can have elastic force with each other and are configured in a plate shape. The elastic part 820 can be integrally formed with the stamp substrate 810. However, it is not limited thereto.

When the elastic part 820 is tensioned due to the pickup of the light-emitting element chip by the pickup portion 830, the elastic energy stored in the elastic part 820 is converted into kinetic energy after the light-emitting element chip is picked up, causing the spring to vibrate.

Assuming that there is no energy loss, according to the law of conservation of energy, elastic energy is continuously converted into kinetic energy, resulting in continuous vibration.

The plurality of pickup portions 830 protrude in the vertical direction from the elastic part 820. The pickup portions 830 can be integrally formed with the elastic part 820. However, it is not necessarily limited thereto.

The first damper part 842 is disposed on top of the elastic part 820 and is in contact with the elastic spacing portion 828 of the elastic part 820. Further, the first damper part 842 is in contact with the side surface of the pickup portion 830.

The second damper part 844 is disposed on both inner side surfaces of the spring tensioning part 812 between the stamp substrate 810 and the elastic part 820.

The first and second damper parts 842 and 844 can contain a polymer having viscoelastic properties, such as PDMS or polyurethane, and a fluid such as water or oil. In particular, a polymer having viscoelastic properties and a fluid such as water or oil have excellent performance in absorbing vibration.

In addition, the first and second damper parts 842 and 844 can contain a viscoelastic material or a viscoelastic material having photosensitive properties.

The viscoelastic material can include acrylic-based, butyl-based, polypropylene-based, silicone-based, and urethane-based rubber. However, it is not limited thereto.

The first and second damper parts 842 and 844 can serve to dampen spring vibration by absorbing or dissipating the elastic energy and kinetic energy that generate the spring vibration.

Thus, the damping ratio of the spring vibration of the elastic part 820 can be adjusted through the stiffness design of the first and second damper parts 842 and 844, thereby maximizing the transfer yield of the light-emitting element chip of the stamp 800.

Hereinafter, a method for fabricating a light-emitting element transfer stamp according to the fourth embodiment of the present disclosure will be described.

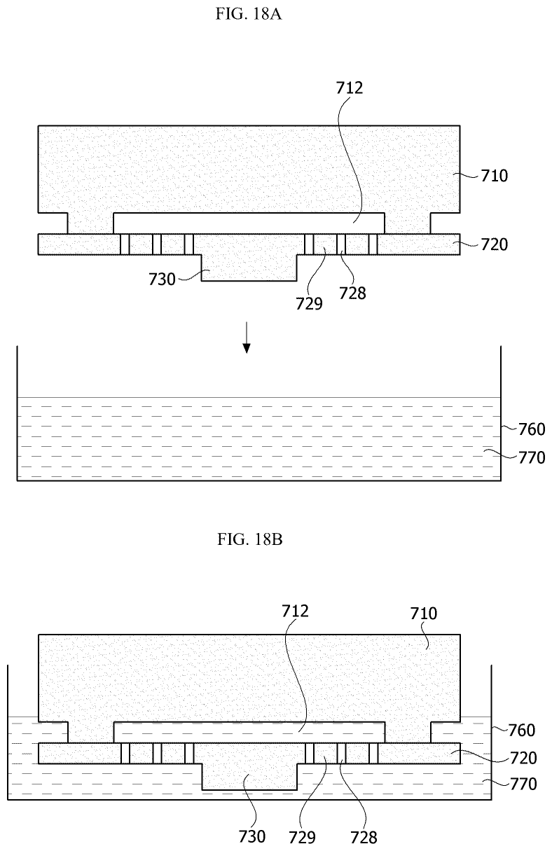

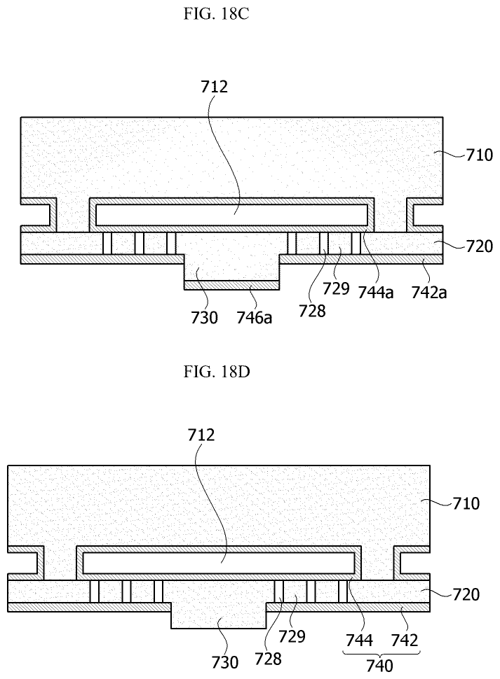

FIGS. 18A to 18D are cross-sectional views of a stamp fabricating process according to the fourth embodiment of the present disclosure.

The process of disposing the elastic part 720 on the stamp substrate 710, the process of forming the spring tensioning part 712 between the stamp substrate 710 and the elastic part 720, and the process of forming the elastic spacing portion 728 and the plurality of leaf springs 729 in the elastic part 720 proceed in the same sequence as the process shown in FIGS. 13A to 13H, and therefore, the description thereof is omitted.

Referring to FIG. 18A, the elastic part 720 is disposed on the stamp substrate 710 to form the spring tensioning part 712 with a certain space therebetween.

As the stamp substrate 710, a quartz substrate, a sapphire substrate, or a silicon substrate can be used. However, the present disclosure is not necessarily limited thereto.

The spring tensioning part 712 with a certain space can provide a space for the elastic part 720 to be tensioned when the pickup portion 730 picks up the light-emitting element 100 on the growth substrate 300 (see FIG. 7A). If the spring tensioning part 712 were not present, the elastic part 720 would not be able to be tensioned when the light-emitting element 100 is picked up.

Next, the elastic spacing portion 728 and the plate-shaped springs 729 in contact with the spring tensioning part 712 are formed in the elastic part 720.

The plurality of leaf springs 729 have elastic force with each other and are configured in a plate shape. The elastic part 720 can be integrally formed with the stamp substrate 710. However, it is not necessarily limited thereto.

When the elastic part 720 is tensioned due to the pickup of the light-emitting element chip by the pickup portion 730, the elastic energy stored in the elastic part 720 is converted into kinetic energy after the light-emitting element chip is picked up, causing the spring to vibrate.

Assuming that there is no energy loss, according to the law of conservation of energy, elastic energy is continuously converted into kinetic energy, resulting in continuous vibration.

Next, the plurality of pickup portions 730 are formed on the top surface of the elastic part 720. The plurality of pickup portions 730 protrude in the vertical direction from the elastic part 720. The pickup portions 730 can be integrally formed with the elastic part 720. However, the present disclosure is not necessarily limited thereto.

Next, referring to FIG. 18A, in order to dip the stamp substrate 710 on which the elastic part 720 and the pickup portion 730 are provided, a container 760 is filled with a liquid polymer material 770.

The liquid polymer material 770 can include a polymer having viscoelastic properties, such as PDMS or polyurethane, and a fluid such as water or oil. In particular, a polymer having viscoelastic properties, and a fluid such as water or oil have excellent performance in absorbing vibration.

The viscoelastic material can include acrylic-based, butyl-based, polypropylene-based, silicone-based, and urethane-based rubber. However, it is not limited thereto.

Next, referring to FIG. 18B, the stamp substrate 710, on which the elastic part 720 and the pickup portion 730 are provided, is dipped into the container 760 for a certain period of time.

Next, referring to FIG. 18C, by dipping the stamp substrate 710 into the container 760, the inner surface of the spring tensioning part, the upper surface of the elastic part 720, and the top surface of the pickup portion 730 are coated with first to third polymer material layers 742a, 744a, and 746a in a liquid state, respectively.

Next, referring to FIG. 18D, the third polymer material layer 746a formed on the top surface of the pickup portion 730, which picks up the light-emitting element, is removed.

Next, the remaining first and second polymer material layers 742a and 744a are subjected to a relaxation and baking process to form the first and second damper parts 742 and 744 on the top surface of the elastic part 720 and the inner surface of the spring tensioning part 714, respectively, thereby completing the process of forming the first and second damper parts 742 and 744 in the stamp 700.

The stamp for transferring light-emitting elements according to various embodiments of the present disclosure can be described as follows.

A stamp for transferring light-emitting elements according to one or more embodiments of the present disclosure can comprise at least one pickup portion configured to pick up a light-emitting element; a substrate configured to move the at least one pickup portion; an elastic part disposed between the pickup portion and the substrate; and a damper part configured to absorb vibration generated in the elastic part.

According to one or more embodiments of the present disclosure, a spring tensioning part can be formed between the substrate and the elastic part.

According to one or more embodiments of the present disclosure, the damper part can include a damper body portion disposed on a rear surface of the substrate, and a damper extension portion extending from the damper body portion and connected to the elastic part.

According to one or more embodiments of the present disclosure, the damper extension portion of the damper part can be inserted into a damper insertion groove provided in the substrate and is connected to the elastic part.

According to one or more embodiments of the present disclosure, the damper part can contain a viscoelastic material.

According to one or more embodiments of the present disclosure, the viscoelastic material can include a polymer having viscoelastic properties, such as PDMS or polyurethane, and a fluid such as water or oil, or includes acrylic-based, butyl-based, polypropylene-based, silicone-based, and urethane-based rubber.

According to one or more embodiments of the present disclosure, a dummy substrate can be further disposed on the damper part.

According to one or more embodiments of the present disclosure, the damper part can be disposed on a top surface of the elastic part, or disposed on the top surface of the elastic part and an inner surface of the spring tensioning part, or disposed only on an inner side surface of the spring tensioning part.

According to one or more embodiments of the present disclosure, the elastic part can be configured as a spring system including a plurality of leaf springs having elastic spacing portions positioned at regular intervals in a horizontal direction with respect to the substrate, or a coil spring.

According to one or more embodiments of the present disclosure, the substrate and the elastic part can be integrally formed, or the substrate and the elastic part are bonded together.

A method of fabricating a display device according to one or more embodiments of the present disclosure can comprise preparing a stamp including at least one pickup portion configured to pick up a light-emitting element, a first substrate configured to move the at least one pickup portion, an elastic part disposed between the pickup portion and the first substrate, and a damper part configured to absorb vibration generated in the elastic part; preparing a growth substrate on which a plurality of light-emitting elements are formed; preparing a display panel in which display areas including a pixel area having a plurality of emission regions are disposed, and a panel substrate on which a pixel driving circuit configured to drive pixels of the display panel is disposed; picking up the plurality of light-emitting elements of the growth substrate using the at least one pickup portion of the stamp; transferring the plurality of light-emitting elements picked up by the stamp to the plurality of emission regions of the display panel disposed on the panel substrate.

According to one or more embodiments of the present disclosure, a spring tensioning part can be formed between the first substrate and the elastic part.

According to one or more embodiments of the present disclosure, the damper part can include a damper body portion disposed on a rear surface of the first substrate, and a damper extension portion extending from the damper body portion and connected to the elastic part.

According to one or more embodiments of the present disclosure, the damper extension portion can be inserted into a damper insertion groove provided in the first substrate and is connected to the elastic part.

According to one or more embodiments of the present disclosure, the damper part can contain a viscoelastic material, wherein the viscoelastic material includes a polymer having viscoelastic properties, such as PDMS or polyurethane, and a fluid such as water or oil, or includes acrylic-based, butyl-based, polypropylene-based, silicone-based, and urethane-based rubber.

According to one or more embodiments of the present disclosure, a dummy substrate can be further disposed on the damper part.

According to one or more embodiments of the present disclosure, the damper part can be disposed on a top surface of the elastic part, or disposed on the top surface of the elastic part and an inner surface of the spring tensioning part, or disposed only on an inner side surface of the spring tensioning part.

According to one or more embodiments of the present disclosure, the first substrate and the elastic part can be integrally formed, or the first substrate and the elastic part are bonded together.

According to one or more embodiments of the present disclosure, the transferring the plurality of light-emitting elements picked up by the stamp to the plurality of emission regions on the panel substrate can include forming a plurality of first electrodes on the panel substrate; and transferring the plurality of light-emitting elements picked up by the stamp onto the plurality of first electrodes.

According to one or more embodiments of the present disclosure, a method can further comprise after said transferring the plurality of light-emitting elements onto the plurality of first electrodes of the panel substrate, disposing a first optical layer between the plurality of light-emitting elements; and disposing a second electrode on the plurality of light-emitting elements and the first optical layer.

The effects of the present disclosure are not limited to the above-mentioned effects, and other effects which are not mentioned will be clearly understood by those skilled in the art from the description in claims.

Although embodiments of the present disclosure have been described in more detail with reference to the accompanying drawings, the present disclosure is not necessarily limited to the embodiments, and various modifications can be carried out without departing from the technical spirit of the present disclosure. Therefore, the embodiments disclosed in the present disclosure are not intended to limit the technical spirit of the present disclosure, but intended to describe the same, and the scope of the technical spirit of the present disclosure is not limited by these embodiments. Therefore, it should be understood that the above-described embodiments are illustrative and not restrictive in all respects.

What is claimed is:

1. A stamp for transferring light-emitting elements, the stamp comprising:
at least one pickup portion configured to pick up a light-emitting element;
a substrate configured to move the at least one pickup portion;
an elastic part disposed between the at least one pickup portion and the substrate; and
a damper part configured to absorb vibration generated in the elastic part.

2. The stamp of claim 1, further comprising a spring tensioning part disposed between the substrate and the elastic part.

3. The stamp of claim 1, wherein the damper part includes a damper body portion disposed on a rear surface of the substrate, and a damper extension portion extending from the damper body portion and connected to the elastic part.

4. The stamp of claim 3, wherein the damper extension portion of the damper part is inserted into a damper insertion groove provided in the substrate and is connected to the elastic part.

5. The stamp of claim 1, wherein the damper part contains a viscoelastic material.

6. The stamp of claim 5, wherein the viscoelastic material includes a polymer having viscoelastic properties, and a fluid, or includes acrylic-based, butyl-based, polypropylene-based, silicone-based, and urethane-based rubber.

7. The stamp of claim 6, wherein the polymer having viscoelastic properties includes PDMS or polyurethane, and the fluid includes water or oil.

8. The stamp of claim 1, further comprising a dummy substrate disposed on the damper part.

9. The stamp of claim 1, wherein the damper part is disposed on a top surface of the elastic part, or is disposed on the top surface of the elastic part and an inner surface of the spring tensioning part, or is disposed only on an inner side surface of the spring tensioning part.

10. The stamp of claim 8, wherein when the damper part is disposed on the top surface of the elastic part, the damper part is in contact with the side surface of the at least one pickup portion.

11. The stamp of claim 1, wherein the elastic part is configured as a spring system including a plurality of leaf springs having elastic spacing portions positioned at regular intervals in a horizontal direction with respect to the substrate, or a coil spring.

12. The stamp of claim 1, wherein the substrate and the elastic part are integrally formed, or the substrate and the elastic part are bonded together.

13. A method for fabricating a display device, the method comprising:
preparing a stamp including at least one pickup portion configured to pick up a light-emitting element, a first substrate configured to move the at least one pickup portion, an elastic part disposed between the at least one pickup portion and the first substrate, and a damper part configured to absorb vibration generated in the elastic part;
preparing a growth substrate on which a plurality of light-emitting elements are formed;
preparing a display panel in which display areas including a pixel area having a plurality of emission regions are disposed, and a panel substrate on which a pixel driving circuit configured to drive pixels of the display panel is disposed;
picking up the plurality of light-emitting elements of the growth substrate using the at least one pickup portion of the stamp;
transferring the plurality of light-emitting elements picked up by the stamp to the plurality of emission regions of the display panel disposed on the panel substrate.

14. The method of claim 13, wherein a spring tensioning part is formed between the first substrate and the elastic part.

15. The method of claim 13, wherein the damper part includes a damper body portion disposed on a rear surface of the first substrate, and a damper extension portion extending from the damper body portion and connected to the elastic part.

16. The method of claim 15, wherein the damper extension portion is inserted into a damper insertion groove provided in the first substrate and is connected to the elastic part.

17. The method of claim 13, wherein the damper part contains a viscoelastic material, wherein the viscoelastic material includes a polymer having viscoelastic properties, and a fluid, or includes acrylic-based, butyl-based, polypropylene-based, silicone-based, and urethane-based rubber.

18. The method of claim 17, wherein the polymer having viscoelastic properties includes PDMS or polyurethane, and the fluid includes water or oil.

19. The method of claim 13, wherein a dummy substrate is further disposed on the damper part.

20. The method of claim 13, wherein the damper part is disposed on a top surface of the elastic part, or disposed on the top surface of the elastic part and an inner surface of the spring tensioning part, or disposed only on an inner side surface of the spring tensioning part.

21. The method of claim 20, wherein in the case of the damper part is disposed on a top surface of the elastic part, the damper part is in contact with the side surface of the at least one pickup portion.

22. The method of claim 13, wherein the first substrate and the elastic part are integrally formed, or the first substrate and the elastic part are bonded together.

23. The method of claim 13, wherein the transferring the plurality of light-emitting elements picked up by the stamp to the plurality of emission regions on the panel substrate includes:
forming a plurality of first electrodes on the panel substrate; and
transferring the plurality of light-emitting elements picked up by the stamp onto the plurality of first electrodes.

24. The method of claim 23, further comprising:
after the transferring of the plurality of light-emitting elements onto the plurality of first electrodes of the panel substrate is performed,
disposing a first optical layer between the plurality of light-emitting elements; and
disposing a second electrode on the plurality of light-emitting elements and the first optical layer.
